(19) United States
(12) Patent Application Publication
(10) Pub. No.: US 2002/0014924 A1
(43) Pub. Date: Feb. 7, 2002

(54) High-C/N-ratio voltage-controlled oscillator allowing oscillating frequency to be easily set

(75) Inventor: Takeshi Tanemura, Fukushima-ken (JP)

Correspondence Address: BRINKS HOFER GILSON & LIONE, P.O. BOX 10395, CHICAGO, IL, 60610, US

(73) Assignee: Alps Electric Co., Ltd.

(21) Appl. No.: 09/967,545

(22) Filed: Sep. 28, 2001

(30) Foreign Application Priority Data
May 10, 2000 (JP) 2000-311727

(51) Int. Cl. H03B 11/10

(52) U.S. Cl. 331/107 SL

(57) ABSTRACT

A voltage-controlled oscillator includes an oscillation transistor and a resonant circuit connected between the ground and the base of the oscillation transistor. The resonant circuit has a main stripline grounded at one end, and a varactor diode grounded at one end. At least a sub stripline capacitively coupled with the main stripline is provided. One end of the sub stripline is grounded through a switching device.

### BACKGROUND OF THE INVENTION

1. Field of the Invention

The present invention relates to voltage-controlled oscillators, and more particularly, to a voltage-controlled oscillator which oscillates in two frequency bands, a 3.5 GHz band and a 3.7 GHz band, and which is used for portable telephones.

2. Description of the Related Art

FIG. 9 shows a conventional voltage-controlled oscillator. The collector of an oscillation transistor 31 is grounded in a high-frequency manner, and feedback capacitors 32 and 33 are connected between the base and the emitter, and between the emitter and the ground, respectively. A resonant circuit 34 is connected between the base of the oscillation transistor 31 and the ground. The resonant circuit 34 includes a varactor diode 35 grounded at the anode, and a stripline 36 grounded at one end.

The cathode of the varactor diode 35 is connected to the other end of the main stripline 36 through a capacitor 37, and the other end of the main stripline 36 is connected to the base of the oscillation transistor 31 through a capacitor 38. The cathode of the varactor diode 35 is also connected to a control terminal 40 through a choke coil 39.

The anode of a diode 42 is connected to a tap point P of the main stripline 36, disposed somewhere in the longitudinal direction of the main stripline 36, through a capacitor (0.5 pF to 1.0 pF) 41, and the cathode of the diode 42 is grounded. The anode is also connected to a switching terminal 44 for frequency-band switching through a resistor 43.

In the above-described structure, when a voltage is not applied to the switching terminal 44, the diode 42 is off (in a non-continuity state). Since the tap point P of the main stripline 36 is grounded by a series circuit formed of the capacitor 41 and the capacitive component of the diode 42, the oscillating frequency becomes high. When the diode 42 is on (in a continuity state), since the tap point P is grounded by the capacitor 41, the oscillating frequency becomes low. The constant of each part and the position of the tap point P are set such that the oscillating frequency obtained when the diode 42 is on falls in the 3.7 GHz band and that obtained when the diode 42 is off falls in the 3.5 GHz band.

When a control voltage applied to the control terminal 40 is changed, the capacitance of the varactor diode 35 is changed, and thereby the oscillating frequency is controlled. An oscillating signal is output from the emitter of the transistor 31.

When the oscillating frequency is high, since the oscillating frequency largely shifts due to a slight difference of the position of the tap point P and a slight difference of the capacitance of the capacitor 41, it is difficult to set them. In particular, the capacitor 41 needs to have a small capacitance, but only a capacitor having a capacitance of 0.5 pF is commercially available in the market as that having a capacitance of 1.0 pF or less. In addition, the tolerance (variation) of the capacitance is as large as 50%, these factors make the oscillating frequency setting further difficult.

When the oscillating frequency becomes as high as 3GHz to 4GHz, the Q value of the capacitor 41 becomes as very low as 15 to 20. Especially when the oscillating frequency falls in the 3.5 GHz band, a high-C/N-ratio oscillating signal cannot be obtained.

### SUMMARY OF THE INVENTION

Accordingly, it is an object of the present invention to provide a voltage-controlled oscillator which allows an oscillating frequency to be easily set and which obtains a high-C/N-ratio oscillating signal.

The foregoing object is achieved according to the present invention through the provision of a voltage-controlled oscillator including an oscillation transistor; and a resonant circuit connected between the base of the oscillation transistor and the ground, wherein the resonant circuit includes a main stripline grounded at one end, a varactor diode grounded at one end, and at least a sub stripline capacitively coupled with the main stripline; and one end of the sub stripline is grounded through switching means.

As described above, according to the present invention, since at least the sub stripline is provided which is capacitively coupled with the main stripline of the resonant circuit connected between the base of the oscillation transistor and the ground, and one end of the sub stripline is grounded through the switching means, the oscillating frequency band is switched by ON/OFF of the switching means. In addition, because the capacitive component caused by the coupling between the main stripline and the sub stripline has a high Q value, an oscillating signal has a high C/N ratio. Furthermore, since the capacitive component caused by this coupling can be specified finely by the gap between the main stripline and the sub stripline and the dimensions of the sub stripline, a degree of freedom in specifying the oscillating frequency band is increased.

In the voltage-controlled oscillator, the other end of the sub stripline may be grounded.

In this case, since the other end of the sub stripline is grounded, a high-C/N-ratio oscillating signal is obtained and the oscillating-frequency band is specified freely.

In the voltage-controlled oscillator, a capacitor may be connected in series to the switching means.

In this case, since the capacitor is connected in series to the switching means, the oscillating frequency band is specified further freely.

In the voltage-controlled oscillator, the switching means may be a diode.

In this case, since the diode serves as the switching means, the oscillating frequency band is easily switched.

In the voltage-controlled oscillator, the switching means may be a transistor.

In this case, since the transistor serves as the switching means, a current required for switching the oscillating frequency band is reduced.

### BRIEF DESCRIPTION OF THE DRAWINGS

FIG. 1 is a circuit diagram showing the structure of a voltage-controlled oscillator according to the present invention.

FIG. 2 is a plan of striplines used in the voltage-controlled oscillator according to the present invention.

FIG. 3 is a plan of other striplines used in the voltage-controlled oscillator according to the present invention.

FIG. 4 is an equivalent circuit diagram of a main section of the voltage-controlled oscillator according to the present invention.

FIG. 5 is an equivalent circuit diagram of a main section of the voltage-controlled oscillator according to the present invention.

FIG. 6 is a circuit diagram showing the structure of another voltage-controlled oscillator according to the present invention.

FIG. 7 is an equivalent circuit diagram of a main section of the another voltage-controlled oscillator according to the present invention.

FIG. 8 is an impedance characteristic diagram of the main section of the another voltage-controlled oscillator according to the present invention.

FIG. 9 is a circuit diagram showing the structure of a conventional voltage-controlled oscillator.

### DESCRIPTION OF THE PREFERRED EMBODIMENTS

Voltage-controlled oscillators according to the present invention will be described below by referring to the drawings.

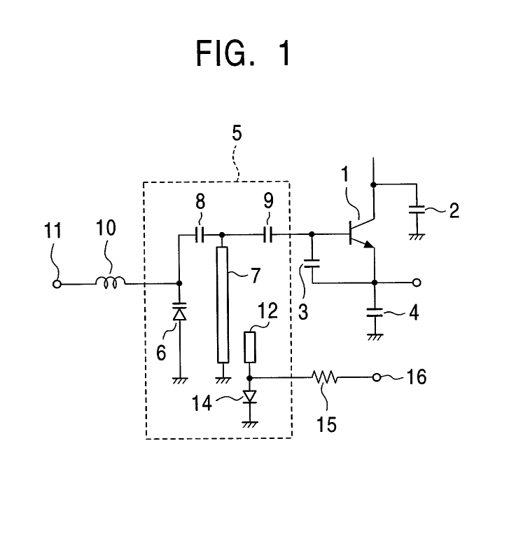

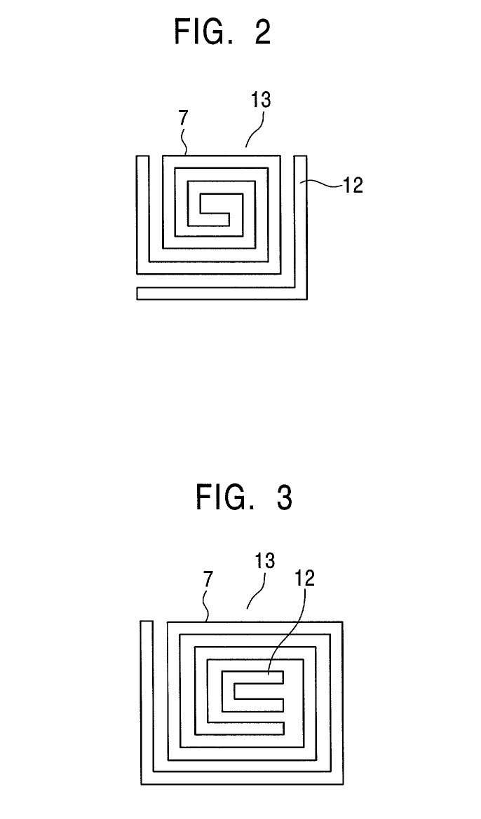

FIG. 1 shows the circuit structure of a voltage-controlled oscillator according to an embodiment of the present invention. The collector of an oscillation transistor 1 is grounded by a capacitor 2 in a high-frequency manner, a feedback capacitor 3 is connected between the base and the emitter, and a feedback capacitor 4 is connected between the emitter and the ground. A resonant circuit 5 is connected between the base of the oscillation transistor 1 and the ground. The resonant circuit 5 has a varactor diode 6 grounded at the anode and a main stripline 7 grounded at one end.

The cathode of the varactor diode 6 is connected to the other end of the main stripline 7 through a capacitor 8, and the other end of the main stripline 7 is connected to the base of the oscillation transistor 1 through a capacitor 9. The cathode of the varactor 6 is also connected to a control terminal 11 through a choke inductor 10.

A sub stripline 12 is provided adjacently to the main stripline 7. The main stripline 7 and the sub stripline 12 are made from conductors formed on a printed circuit board 13. The main stripline 7 is formed in a spiral shape, and the sub stripline 12 is formed along the surrounding of the main stripline 7. As shown in FIG. 3, the sub stripline 12 may be formed inside the spiral-shaped main stripline 7. The main stripline 7 is about 8 mm long and about 600 μm wide, and the sub stripline 12 is about 2 mm long and about 300 μm wide. The gap between the main stripline 7 and the sub stripline 12 is about 100 μm.

One end of the sub stripline 12 is connected to the anode of a diode 14, and the cathode of the diode 14 is grounded. The anode of the diode 14 is also connected to a switching terminal 16 through a resistor 15. A transistor (not shown) may be used instead of the diode 14.

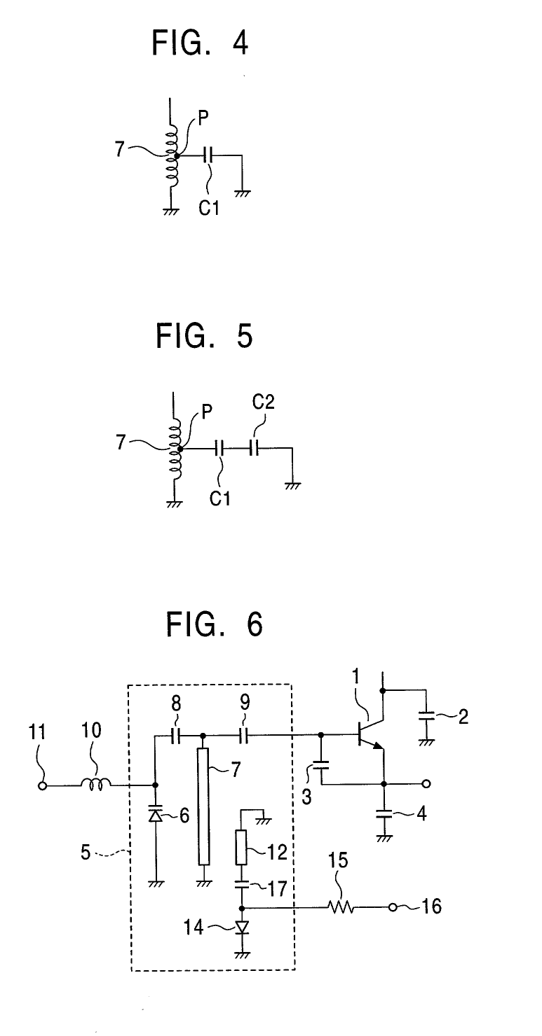

In the above-described structure, a capacitor C1 is formed between the main stripline 7 and the sub stripline 12 mainly through the printed circuit board 13. The capacitance of the capacitor C1 is determined by the length of the sub stripline 12 and the gap between the main stripline 7 and the sub stripline 12, and is about 0.1 to 0.2 pF with the above-described dimensions. FIG. 4 shows an equivalent circuit of the circuit section ranging from the main stripline 7 to the diode 14, obtained when a voltage is applied to the switching terminal 16 to turn on (continuity state) the diode 14. FIG. 5 shows an equivalent circuit obtained when the diode is turned off (in a non-continuity state). In FIG. 5, C2 indicates the capacitive component of the diode 14 across its terminals obtained when the diode 14 is off, and is about 0.5 pF.

In FIGS. 4 and 5, since a virtual coupling point P where the capacitive component C1 is coupled with the main stripline 7 is opposite the center point of the sub stripline 12 in its longitudinal direction, when the sub stripline 12 is shifted in the longitudinal direction of the main stripline 7, the position of the virtual coupling point P is changed.

When the diode 14 is on, the oscillating frequency becomes low because the capacitance of a capacitor generated between the virtual coupling point P and the ground becomes large. When the diode 14 is off, the oscillating frequency becomes high because the capacitance becomes small.

The constant of each part, the position of the virtual coupling point P, and the capacitive component C1 between the two striplines are set such that the oscillating frequency obtained when the diode 14 is on falls in the 3.5 GHz band and that obtained when the diode 14 is off falls in the 3.7 GHz band. The capacitance of the capacitive component C1 can be finely specified by the gap between the two striplines and the length of the sub stripline 12. The position of the virtual coupling point P can also be specified finely by the position of the sub stripline 12. Therefore, the degree of freedom in specifying a frequency band when the diode 14 is on or off becomes high. A capacitor (not shown) may be inserted between the sub stripline 12 and the diode 14. In this case, the degree of freedom in specifying a frequency band becomes further high.

When a control voltage applied to the control terminal 11 is changed, the capacitance of the varactor diode 6 is changed, and thereby, the oscillating frequency is controlled. An oscillating signal is output from the emitter of the oscillation transistor 1.

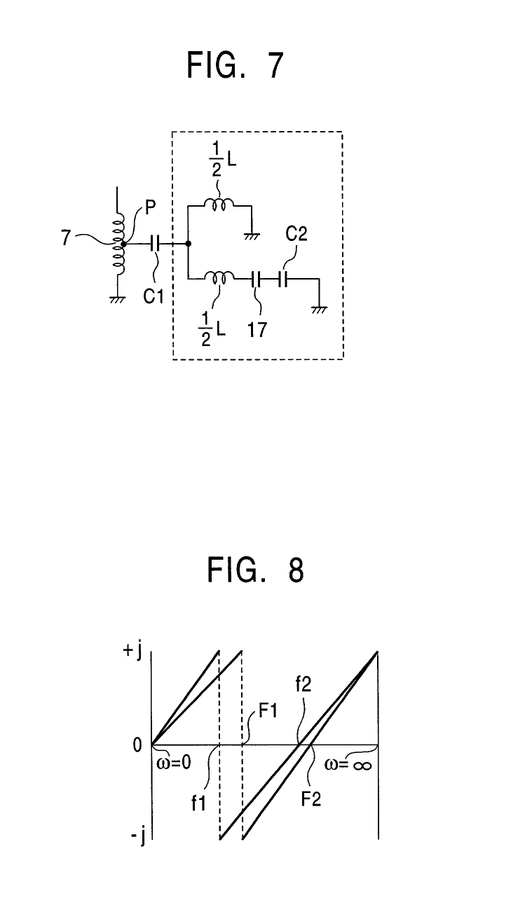

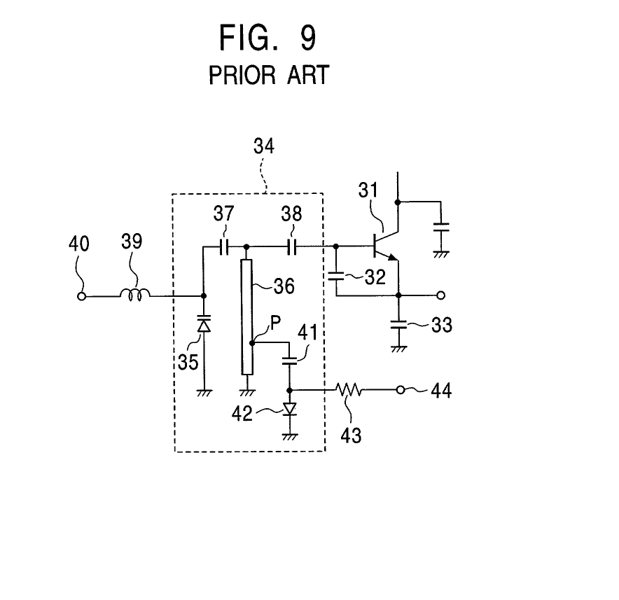

FIG. 6 shows a structure in which the other end of the sub stripline 12 shown in FIG. 1 is grounded, and a capacitor 17 is inserted between the one end of the sub stripline 12 and the anode of the diode 14. In this case, FIG. 7 shows an equivalent circuit corresponding to the circuit section ranging from the main stripline 7 to the diode 14. An inductor component L/2 corresponds to half the length of the sub stripline 12, and a capacitive component C2 is short-circuited when the diode 14 is on.

FIG. 8 shows the impedance characteristics of the sub stripline 12, the capacitor 17, and the capacitive component C2 of the diode 14 shown in FIG. 7. A parallel-resonant frequency F1 and a series-resonant frequency F2 higher than F1 are provided. When the diode 14 is turned on, the parallel-resonant frequency and the series-resonant frequency become lower to f1 and f2. When the dimensions of the sub stripline 12 and the capacitance (several picofarads) of the capacitor 17 are specified such that the oscillating frequency bands (3.5 GHz to 3.7 GHz) are disposed between the parallel-resonant frequency F1 and the series-resonant frequency f2, the entire equivalent capacitance obtained when the diode 14 is on becomes large. As a result, the oscillating frequency band becomes low when the diode 14 is on and becomes high when the diode 14 is off.

When a transistor is used instead of the diode 14, an ON-time current is reduced.

What is claimed is:

1. A voltage-controlled oscillator comprising:
an oscillation transistor; and
a resonant circuit connected between the base of the oscillation transistor and the ground,
wherein the resonant circuit comprises:
a main stripline grounded at one end;
a varactor diode grounded at one end; and
at least a sub stripline capacitively coupled with the main stripline, and
one end of the sub stripline is grounded through switching means.

2. A voltage-controlled oscillator according to claim 1, wherein the other end of the sub stripline is grounded.

3. A voltage-controlled oscillator according to claim 1, wherein a capacitor is connected in series to the switching means.

4. A voltage-controlled oscillator according to claim 1, wherein the switching means is a diode.

5. A voltage-controlled oscillator according to claim 1, wherein the switching means is a transistor.
